(19) United States
(12) Patent Application Publication
(10) Pub. No.: US 2006/0163643 A1
(43) Pub. Date: Jul. 27, 2006

(54) Double gate memory cell with improved tunnel oxide

(76) Inventor: Klaus-Dieter Ufert, Unterschleissheim (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/300,849

(22) Filed: Dec. 15, 2005

(30) Foreign Application Priority Data
Dec. 15, 2004 (DE) 10 2004 060 375.8

(51) Int. Cl. H01L 29/788

(52) U.S. Cl. 257/315

(57) ABSTRACT

Provides a double gate memory cell having a silicon substrate with an active region having a channel region and source/drain regions, the active region forming a ridgelike fin with at least the channel region. A tunnel oxide layer is formed at least partly on the surface of the ridgelike fin of the active region. A floating gate for storing electrical charges is formed at least partly on the surface of the tunnel oxide layer. An intergate insulator layer made of a dielectric material is formed at least partly on the surface of the floating gate. A control gate is formed at least partly on the surface of the intergate layer, the tunnel oxide layer including an amorphous silicon dioxide/titanium dioxide mixed oxide.

### CROSS-REFERENCE TO RELATED APPLICATIONS

This Utility patent application claims priority to German Patent Application No. DE 10 2004 060 375.8, filed on Dec. 15, 2004, which is incorporated herein by reference.

### BACKGROUND

The present invention relates to semiconductor components, and in particular to a double gate memory cell such as is typically used in flash memories.

Primarily with regard to modern portable devices, such as MP3 players and digital cameras, the demand for inexpensive and high-density mass storage devices has increased greatly in recent years. In order to increase the storage density, it is essential to reduce the memory cell size, but this entails a series of problems, such as, for instance, structure inaccuracies and narrow process windows. In particular, parasitic coupling currents increase in the course of scaling, which primarily gives rise to problems in the case of adjacent floating gates in memory cell arrangements of the NAND type. Furthermore, shrinking the tunnel oxide layer is problematic with regard to the programming and data retention properties of the memory cells since undesirable short-channel effects become greater in the course of shrinking the channel lengths. In particular, a reduced channel length in flash memory cells of the NOR type requires an increased dopant concentration of the channel in order to prevent a punch-through of the channel. However, an increased dopant concentration is also accompanied by an increase in the electric field at the interface and an increase in the junction leakage current, whereby the data retention characteristic (“retention time”) is disadvantageously impaired.

A solution to these problems appears to be possible only by significant changes to the configuration of flash memory cells. The specific embodiment of the channel region as a ridgelike fin has proved to be advantageous in this regard, said fin enabling the channel region to be accessible from a plurality of sides.

FIG. 1 schematically illustrates a typical construction of such a transistor, called a FinFET, in which the channel region is formed as a fin. Accordingly, a ridgelike fin 2 having an active region with drain region 3 and source region 4 is formed on a silicon substrate 1. A channel region, which cannot readily be discerned, is situated between the drain region 3 and the source region 4. A floating gate 5 is formed in a manner adjoining the channel region, a tunnel oxide layer 7 being situated between the channel region and the floating gate 5 and serving for electrons to tunnel through between the channel region and the floating gate. Furthermore, an insulator layer 6 made of a dielectric material is deposited between the floating gate and the silicon substrate.

In FinFETS of this type, it is possible at the present time to realize a minimum feature size of approximately 50 nm essentially whilst avoiding the above disadvantages. In comparison with planar transistor structures, the channel breakdown effect can be avoided through corresponding adaptation of the channel thickness. The properties depending on an applied drain voltage are likewise advantageous (see K. Kim, G.-W. Koh: Proc. 24th Conference on Microelectronics, Vol. 1. Nis, May 16-19, 2004).

In the case of NOR flash memory technology, however, scaling limits are encountered even with use of the FinFET channel arrangement, since the energy barrier for the tunneling process of the electrons from the channel region into the floating gate is not lowered by the scaling procedure. As is known, the barrier height in the case of a typical silicon substrate and a typical tunnel oxide layer made of silicon dioxide is relatively high and is approximately 3.1 electron volts (eV). Thus, in the case of this technology, sufficiently high voltages are required between the control gate and drain in order to generate “hot electrons” which can tunnel via the Si/SiO₂ tunneling barrier into the floating gate. However, scaling of the transistor structures is also necessarily accompanied by scaling of the drain voltage, which, however, cannot be lowered below a critical value predetermined by the barrier height of the tunneling barrier. On the other hand, it must be taken into consideration that a sufficiently high barrier ensures the data retention characteristic of the memory cell, so that an excessively low energy barrier for the tunneling of electrons through the tunnel oxide layer is not desirable from this standpoint.

In NAND flash technology, the electrons pass through the tunnel oxide into the floating gate by means of Fowler-Nordheim tunneling. Both for programming and for erasure, very high voltages of, for example, approximately ±18 volts are required at the control gate. These high electric fields cause a series of parasitic effects in the closely adjacent structures and necessitate an additional outlay for instance in the form of charge pumps. The tunnel oxide layer used is usually a weakly nitrided silicon dioxide layer, but the layer thickness thereof cannot be reduced to less than approximately 8 nm since otherwise so-called single bit failures in the tunnel oxide greatly impair the data retention characteristic. In order to realize sufficiently high tunneling currents, one is thus forced to apply correspondingly high voltages to the control gate.

In order to achieve a minimum feature size of less than 80 nm in NOR flash memories, experts are currently discussing the use of materials having a high dielectric constant K (“high-K materials”) as tunnel oxide, by means of which the energy barrier for the tunneling of electrons can be lowered (see Research Trends IFX/CPR, Special edition (2002).

In this undertaking, at the present time hafnium oxide is favored as tunnel oxide layer material, with which, in the case of a silicon substrate, a low energy barrier of approximately 1.5 eV for the tunneling of electrons can possibly be achieved. Accordingly, although hafnium oxide would on the one hand have the advantage of a low drain voltage for the injection of the hot electrons, on the other hand it is disadvantageous with regard to the data retention characteristic. Moreover, hafnium oxide causes a larger number of defects at the interface with the silicon channel region on account of the mismatch of the amorphous short-range order network with the crystalline silicon channel surface.

In the case of the flash memory cells with a NAND configuration, the Fowler-Nordheim tunneling current always requires high voltages for the tunneling through the silicon dioxide tunnel layer, which fundamentally constitute a problem. For this reason, at the present time there is no conclusive concept as to how disturbance-free scaling of NOR and NAND memory cells with a minimum feature size of less than 80 nm can be achieved.

### SUMMARY

One embodiment of the present invention provides a flash memory cell (double gate memory cell) by means of which a minimum feature size of less than 80 nm can be realized.

One embodiment of the invention proposes a double gate memory cell (flash memory cell) having a silicon substrate with an active region, a channel region and source/drain regions being formed in the active region. In this case, the active region forms a ridgelike fin having at least the channel region. A tunnel oxide layer is formed at least partly on the surface of the ridgelike fin of the active region. A floating gate for storing electrical charges is formed at least partly on the surface of the tunnel oxide layer. An intergate insulator layer made of a dielectric material is formed at least partly on the surface of the floating gate, and a control gate is formed at least partly on the surface of the intergate insulator layer.

The double gate memory cell according to one embodiment of the invention includes the tunnel oxide layer having an amorphous silicon dioxide/titanium dioxide mixed oxide. In the mixed oxide, the proportion of silicon dioxide can fundamentally be varied in a range of greater than 0% to less than 100%. Equally, the proportion of titanium dioxide in the mixed oxide can fundamentally be varied in a range of greater than 0% to less than 100%, the sum of the relative proportion of silicon dioxide and the relative proportion of titanium dioxide always giving 100%.

In one embodiment, the use of an amorphous silicon dioxide/titanium dioxide mixed oxide affords the possibility of reducing the energy barrier (barrier height) for the tunneling of electrons through the tunnel oxide layer. The barrier height can thus be set in a range of less than approximately 3.1 eV for pure silicon dioxide up to above approximately 1.3 eV for pure titanium dioxide. In comparison with the hafnium oxide known in the prior art, the amorphous silicon dioxide/titanium dioxide mixed oxide used according to one embodiment of the invention affords that the mixed oxide can be continuously mixed within the (excluded) limits of 100% silicon dioxide and 100% titanium dioxide, so that the barrier height and a figure of merit derived from the dielectric constant and the breakdown field strength can be set in controllable fashion. In other words, by burying the mixing ratio of the amorphous silicon dioxide/titanium dioxide mixed oxide, it is possible to set the barrier height to any value between the above limit values of approximately 3.1 eV and approximately 1.3 eV, according to one embodiment of the invention a value of approximately 2 eV being regarded as optimal in respect of a reduction of the drain voltage and a sufficient data retention characteristic for a NOR memory cell. A dielectric constant is also coupled to this value, so that the silicon-dioxide-equivalent layer thickness can become less than approximately 6 nm and the data retention characteristic can be improved.

In contrast to the hafnium dioxide known in the prior art, it is not to be expected that the defect density of the amorphous silicon dioxide/titanium dioxide mixed oxide used according to one embodiment of the invention will be higher than that in the nitrided silicon dioxide that is conventionally used for this purpose. In the case of a NAND memory cell, the amorphous silicon dioxide/titanium dioxide mixed oxide used according to one embodiment of the invention as the tunnel oxide layer results in the reduction of the voltage value for the control gate voltage for the tunneling of the electrons since, on account of the higher dielectric constant, the strength of the electric field or of the voltage across the tunnel oxide which is required for programming or erasure is lower than in the conventional case. The requirements made of the layer thickness of the tunnel oxide are thus lower as well. Nevertheless, the possibility is also afforded, given a voltage remaining the same, of increasing the tunnel oxide layer thickness on account of the larger charge induction and thus reducing the influence of single bit failures and improving the data retention characteristic. An indication about the relative proportions of silicon dioxide and titanium dioxide that have to be present in the amorphous silicon oxide/titanium oxide mixed oxide used according to the invention (linear mixing rule) in order to set a concrete barrier height and an appropriate dielectric constant can be gathered from C. Misiano, E. Simonetti; Vacuum Vol. 27, No. 4 (1978), page 403.

In one refinement of the double gate memory cell according to one embodiment of the invention, silicon dioxide is present in the silicon dioxide/titanium dioxide mixed oxide used according to the invention in a proportion of at least 50% and less than 100%, as a result of which it is possible to achieve a good compromise between a reduction of the barrier height for the tunneling of electrons and a sufficient data retention characteristic.

In one refinement of the double gate memory cell according to one embodiment of the invention, silicon dioxide is present in the silicon dioxide/titanium dioxide mixed oxide used according to the invention in a proportion in the range of 55%-60%, as a result of which it is possible to obtain an optimum compromise between lowering the barrier height for the tunneling of electrons and a sufficient data retention characteristic. According to one embodiment of the invention, the barrier height for the tunneling of electrons through the tunnel oxide is approximately 2 eV.

In a further refinement of the double gate memory cell according to one embodiment of the invention, the floating gate is produced from an, in particular, p-conducting cobalt silicide and/or nickel silicide instead of from an n-conducting polysilicon in the conventional manner. What can be achieved as a result of this is that, on the side of the floating gate, the barrier height for the tunneling of electrons through the tunnel oxide layer is increased by the difference in the Fermi level of n-polysilicon p-Co/Ni silicide.

In a further refinement of the double gate memory cell according to one embodiment of the invention, a layer made of pure silicon dioxide is formed between the active region and the tunnel oxide layer, which layer made of pure silicon dioxide is, in one case, a few (for example, 2-3) monolayers thick. As a result of this it is possible to optimize the interface properties with respect to the silicon channel region at the boundary of the amorphous silicon dioxide/titanium dioxide mixed oxide without this giving rise to an internal interface with corresponding defects with respect to the amorphous silicon dioxide/titanium dioxide mixed oxide.

Furthermore, one embodiment of the invention relates to a flash memory chip having an arrangement of programmable and erasable double gate memory cells according to the invention as are described above. In a typical structure of the NOR type of the flash memory chip, a multiplicity of memory cells is in each case connected to one of first current lines (for example, bit lines), whereby NOR memory cell blocks are formed. In this case, in each NOR memory cell block each memory cell is connected to the associated first current line at a first terminal and to the silicon substrate at a second terminal. The floating gates of different memory cells of the NOR memory cell block are, moreover, in each case connected to a separate second current line (for example, word line). In a typical structure of the NAND type of the flash memory chip, a multiplicity of series-connected memory cells is in each case connected to one of first current lines (for example, bit lines) whereby NAND memory cell blocks are formed. In this case, each individual NAND memory cell block is connected to the associated first current line at a first terminal and to the silicon substrate at a second terminal, and the floating gates of different memory cells of a NAND memory cell block are in each case connected to a separate second current line (for example, word line).

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 schematically illustrates a perspective view of a conventional FinFET transistor structure.

FIG. 2 schematically illustrates a double gate memory cell according to one embodiment of the invention.

FIG. 3 schematically illustrates an energy band diagram of and also a cross section through a double gate memory cell according to one embodiment of the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

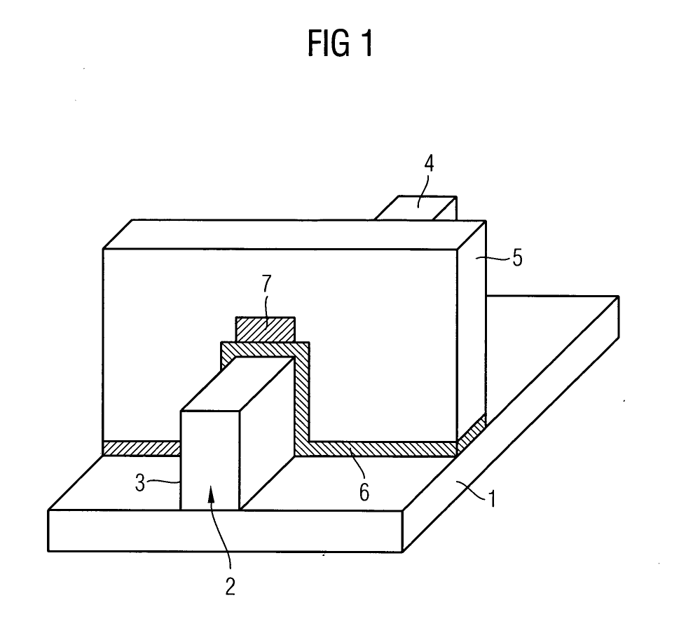

FIG. 1 schematically illustrates a perspective view of a conventional FinFET transistor structure and is described above in the Background of the Invention.

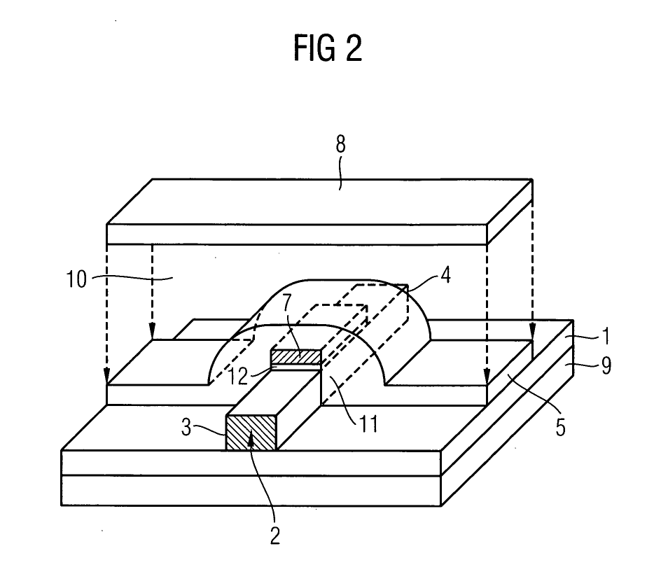

FIG. 2 schematically illustrates a double gate memory cell according to one embodiment of the invention. Accordingly, a ridge-type fin 2 is formed on an n-type silicon substrate 1 backed by an insulator material 9, an active region being formed in said fin. The active region comprises a drain region 3 and a source region 4, and also an intervening channel region 11. The channel region 11 is surrounded by a floating gate 5 on a side parallel to the substrate surface, and also on the two sides perpendicular to the substrate surface. A tunnel oxide layer 7 is formed between the floating gate 5 and the channel region 11 on the side parallel to the substrate surface, through which tunnel oxide layer electrons can tunnel for charging or discharging the floating gate 5. An insulator layer (not illustrated) is deposited between the floating gate and the silicon substrate. An intergate insulator layer 10 made of a dielectric material is situated on the floating gate 5. The control gate 8, which here is identical to a word line, is formed on the intergate insulator layer 10. Moreover, a layer 12 made of pure silicon dioxide and having a thickness of 2-3 monolayers is deposited between the tunnel oxide layer 7 and the channel region 11.

In the double gate memory cell according to one embodiment of the invention, the tunnel oxide of the tunnel oxide layer 7 includes an amorphous silicon dioxide/titanium dioxide mixed oxide, silicon dioxide being present in the mixed oxide in a relative proportion in the range of 55-60% in order to realize an energy barrier for the tunneling of electrons through the tunnel oxide layer of approximately 2 eV. Furthermore, the floating gate 5 is produced from a p-conducting cobalt and/or nickel silicide.

The double gate memory cell according to one embodiment of the invention illustrated in FIG. 2 is based on NOR and NAND flash memory technology. The channel region has a specific fin-type geometry in this case. The fabrication of a conventional FinFET memory cell is well known to the person skilled in the art and need not be explained in any greater detail here. A plurality of methods, such as, for instance, plasma CVD (chemical vapor deposition), thermal CVD, ALD, reactive co-sputtering of titanium and silicon targets by means of medium-frequency pulsed operation, can be used for depositing the amorphous silicon dioxide/titanium dioxide mixed oxide layer used in the double gate memory cell according to one embodiment of the invention. A high-temperature LPCVD method is used in one case. This proceeds from the chemical substances tetraethyl orthosilicate, TEOS, for SiO₂ and tetraethyl orthotitanate for TiO₂. These substances are readily intermixable starting substances (liquids) tried and tested over many years, for the deposition of the two oxides. In principle, it is also possible to use other starting substances such as, for example, tetramethyl orthosilicate (TMOS) or hexamethyldisiloxane (HDMSO) for SiO₂ and tetraisopropyl titanate for TiO₂. High-temperature reactors such as are usually used in semiconductor chip fabrication can normally be used for the deposition. When feeding the substances in gaseous form, care must be taken to ensure that the supply lines are heated sufficiently, since otherwise the gases condense on the tube wall. There are commercially available systems for this, such as, for example, liquid delivery system LDS-300, manufacturer: Advanced Technology Materials, which convert the liquids into a gaseous form (“Bubbler” or pumpsystems), and also MFCs that are designed in a corresponding manner in order to prevent undesirable condensation.

A substrate temperature of 635° C. and a pressure of 525 mtorr are chosen in the fabrication of the double gate memory cell according to one embodiment of the invention illustrated in FIG. 2. Given corresponding gas flows, the deposition rates lie in the range of 1-1.5 nm/min. With the respective gas flows, the desired composition of the amorphous silicon dioxide/titanium dioxide mixed oxide can be set in a continuously variable manner in the range of greater than 0% silicon dioxide to less than 100% silicon dioxide, and greater than 0% titanium dioxide to less than 100% titanium dioxide, the sum of silicon dioxide and titanium dioxide giving 100%. In order to improve the interface properties with respect to the silicon channel region, one case begins with 2-3 monolayers of SiO₂ on the silicon channel region and subsequently deposits the amorphous silicon dioxide/titanium dioxide mixed oxide with the desired proportion of silicon dioxide, which, however, should be at least 50%, with an overall layer thickness of approximately 10 nm. For a concrete setting of the barrier height to approximately 2 eV and the adequate dielectric constant, the linear mixing, as shown by Misiano et al., of the two oxides is used and a composition in the range of 55-60% relative proportion of silicon dioxide is sought. The amorphous silicon dioxide/titanium dioxide mixed oxide layer may optionally be densified by means of a momentary RTP step in order, if necessary, to further reduce the defect density in the mixed oxide.

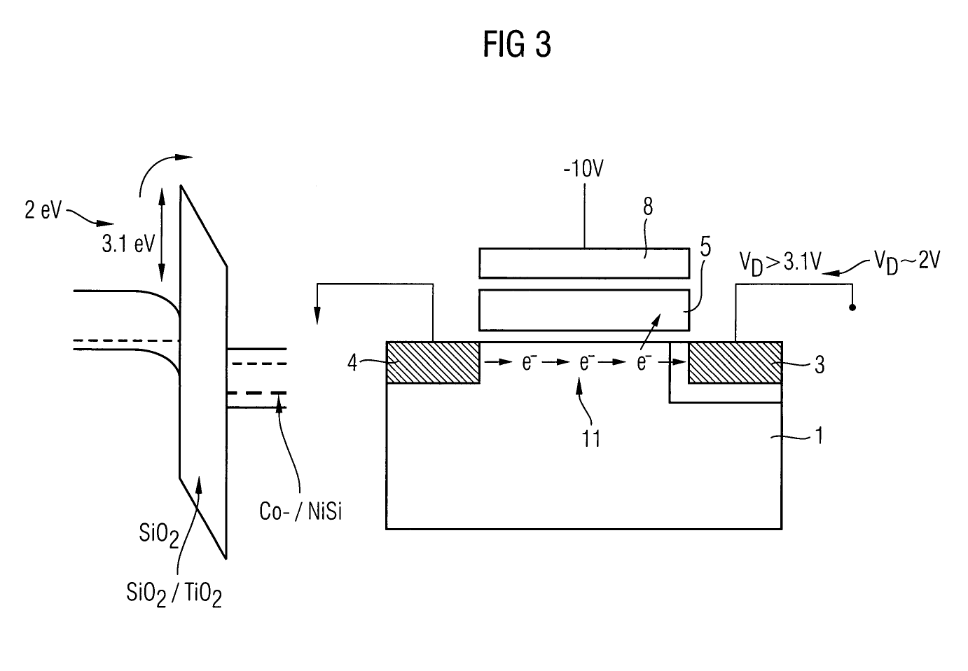

Reference is now made to FIG. 3, which schematically illustrates an energy band diagram of the double gate memory cell according to one embodiment of the invention and also a cross section through said memory cell. In the energy band diagram, the possible improvements by means of the double gate memory cell according to one embodiment of the invention are symbolically represented by the arrows. Proceeding from the conventional case, in which, given a silicon substrate, SiO₂ is used as material of the tunnel oxide layer and polysilicon is used as material of the floating gate, which results in a barrier height for the tunneling of electrons through the tunnel oxide layer of approximately 3.1 eV, the use of amorphous silicon dioxide/titanium dioxide mixed oxide as tunnel oxide layer material makes it possible to set a barrier height of approximately 2 eV, which is regarded as optimal in respect of the necessary voltages for programming and erasing the memory cell and also the data retention characteristic. Furthermore, through the use of cobalt and/or nickel silicide (Co—/NiSi) as floating gate material, on the side of the floating gate, it is possible to increase the energy barrier by the difference in Fermi levels between n-polysilicon and p-Co/Ni silicide.

The sectional illustration of the double gate memory cell according to one embodiment of the invention illustrates that, for programming the memory cell, with a control gate voltage of for example, 10 V being applied, the drain voltage V_{D} can be reduced from V_{D}>3.1 V in the conventional case to V_{D}≈2V for a double gate memory cell according to one embodiment of the invention.

In the double gate (flash) memory cell according to one embodiment of the invention, the hitherto used tunnel oxide layer made of weakly nitrided silicon dioxide or made of a hafnium dioxide favored for smaller feature sizes is replaced by a tunnel oxide layer made of an amorphous silicon dioxide/titanium dioxide mixed oxide. In this case, it is possible to achieve a barrier height—regarded as optimal—of approximately 2 eV for the tunneling of electrons through the tunnel oxide layer. The mixed oxide has a specific (definable) composition which makes it possible to set a specific (definable) dielectric constant from a linear mixing rule for the two oxides of the mixed oxide according to one embodiment of the invention. Furthermore, the floating gate may include a, for example, p-conducting material such as cobalt silicide or nickel silicide in order to furthermore improve the data retention characteristic. In order to attain a minimum feature size in the region of approximately 80 nm or even below that, the embodiment of the memory cell in a FinFET configuration is chosen since the channel length can be reduced as a result of this, for example in the case of a NOR memory cell. In the case of NAND memory cells, the FinFET structure enables a higher memory cell transistor current. Since the transistor current is likewise reduced in the scaling of the conventional NAND memory cell structures, the signal margin would be critical without a FinFET structure.

In the case of the amorphous silicon dioxide/titanium dioxide mixed oxide used as tunnel oxide in the double gate memory cell according to one embodiment of the invention, the barrier height for the tunneling of electrons through the tunnel oxide layer can be set in a defined manner, with the result that it is possible to achieve an optimum of reduced drain voltage and sufficient data retention characteristic in NOR flash memory cell technology in the region of minimum feature sizes below 80 nm. A value of approximately 2V drain voltage is sought in this case. By virtue of the amorphous silicon dioxide/titanium dioxide mixed oxide used according to one embodiment of the invention, in NAND flash memory cell technology, given an unchanged layer thickness and defect density in comparison with the nitrided silicon dioxide layer currently used, it is possible to reduce the programming and erasing voltage at the control gate. On the other hand, there is both the possibility, given an unchanged voltage at the control gate, of increasing the layer thickness of the amorphous silicon dioxide/titanium dioxide mixed oxide in order thereby to reduce the influence of the single bit failures and to improve the data retention characteristic, and the possibility of achieving a compromise between reduced voltage at the control gate and improved data retention characteristic.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A double gate memory cell comprising:
a silicon substrate with an active region having a channel region and source/drain regions, the active region forming a ridgelike fin comprising at least the channel region;
a tunnel oxide layer, which is formed at least partly on the surface of the ridgelike fin of the active region;
a floating gate for storing electrical charges which is formed at least partly on the surface of the tunnel oxide layer;
an intergate insulator layer made of a dielectric material, which is formed at least partly on the surface of the floating gate; and
a control gate, which is formed at least partly on the surface of the intergate layer,
wherein the tunnel oxide layer comprises an amorphous silicon dioxide/titanium dioxide mixed oxide.

2. The double gate memory cell of claim 1, wherein the silicon dioxide titanium dioxide mixed oxide has a relative proportion of silicon dioxide in the mixed oxide of at least 50% and less than 100%.

3. The double gate memory cell of claim 1, wherein the silicon dioxide/titanium dioxide mixed oxide has a relative proportion of silicon dioxide in the mixed oxide in the range of 55%-60%.

4. The double gate memory cell of claim 2, wherein the energy barrier for the tunneling of electrons through the tunnel oxide layer is approximately 2 eV.

5. The double gate memory cell of claim 1, wherein the floating gate comprises one or more materials selected from the group consisting of cobalt silicide and nickel silicide.

6. The double gate memory cell of claim 1, wherein a layer made of pure silicon dioxide is formed between the active region and the tunnel layer.

7. The double gate memory cell of claim 6, wherein the layer made of pure silicon dioxide is a few monolayers thick.

8. A flash memory chip comprising:
an arrangement of programmable and erasable double gate memory cells being arranged in rows and columns and being connected to a multiplicity of first and second current lines, at least one of the double gate memory cells further comprising:
a silicon substrate with an active region having a channel region and source/drain regions, the active region forming a ridgelike fin comprising at least the channel region;
a tunnel oxide layer, which is formed at least partly on the surface of the ridgelike fin of the active region;
a floating gate for storing electrical charges which is formed at least partly on the surface of the tunnel oxide layer;
an intergate insulator layer made of a dielectric material, which is formed at least partly on the surface of the floating gate; and
a control gate, which is formed at least partly on the surface of the intergate layer,
wherein the tunnel oxide layer comprises an amorphous silicon dioxide/titanium dioxide mixed oxide.

9. The flash memory chip of claim 8, which has a structure of the NOR type in which a multiplicity of memory cells is in each case connected to one of the first current lines and NOR memory cell blocks are formed, in each NOR memory cell block each memory cell being connected to the associated first current line at a first terminal and to the silicon substrate at a second terminal, and the floating gates of different memory cells of the NOR memory cell block in each case being connected to a separate second current line.

10. The flash memory chip of claim 8, which has a structure of the NAND type in which a multiplicity of series-connected memory cells are in each case connected to one of the first current lines and NAND memory cell blocks are formed, each NAND memory cell block being connected to the associated first current line at a first terminal and to the silicon substrate at a second terminal, and the floating gates of different memory cells of the NAND memory cell block in each case being connected to a separate second current line.

11. A double gate memory cell comprising:
a silicon substrate;
an active region having a channel region and source/drain regions, the active region forming a ridgelike fin;
means formed on a surface of the ridgelike fin for setting a barrier height for the tunneling of electrons between approximately 3.1 eV and approximately 1.3 eV.
a floating gate for storing electrical charges that is formed on a surface of the tunnel oxide layer;
an intergate insulator layer made of a dielectric material formed on a surface of the floating gate; and
control gate formed on a surface of the intergate layer.

12. The double gate memory cell of claim 11, wherein the means for setting a barrier height includes a tunnel oxide layer.

13. The double gate memory cell of claim 12, wherein the tunnel oxide layer comprises an amorphous silicon dioxide/titanium dioxide mixed oxide.

14. The double gate memory cell of claim 12, wherein the silicon dioxide titanium dioxide mixed oxide has a relative proportion of silicon dioxide in the mixed oxide of at least 50% and less than 100%.

15. The double gate memory cell of claim 12, wherein the silicon dioxide/titanium dioxide mixed oxide has a relative proportion of silicon dioxide in the mixed oxide in the range of 55%-60%.

16. The double gate memory cell of claim 12, wherein the energy barrier for the tunneling of electrons through the tunnel oxide layer is approximately 2 eV.

17. The double gate memory cell of claim 12, wherein the floating gate comprises one or more materials selected from the group consisting of cobalt silicide and nickel silicide.

18. The double gate memory cell of claim 12, wherein a layer made of pure silicon dioxide is formed between the active region and the tunnel layer.

19. The double gate memory cell of claim 12, wherein the layer made of pure silicon dioxide is a few monolayers thick.
